(19) United States
(12) Patent Application Publication
(10) Pub. No.: US 2025/0008719 A1
(43) Pub. Date: Jan. 2, 2025

(54) SRAM FORMATION FOR VERTICAL FET TRANSISTOR WITH BACKSIDE CONTACT

(71) Applicant: INTERNATIONAL BUSINESS MACHINES CORPORATION, ARMONK, NY (US)

(72) Inventors: Min Gyu Sung, Latham, NY (US); Ruilong Xie, Niskayuna, NY (US); Julien Frougier, Albany, NY (US); Chanro Park, Clifton Park, NY (US); Juntao Li, Cohoes, NY (US); Tao Li, Slingerlands, NY (US)

(21) Appl. No.: 18/344,838

(22) Filed: Jun. 29, 2023

(51) Int. Cl. H10B 10/00; H01L 21/8238; H01L 27/092; H01L 29/66; H01L 29/78

(52) U.S. Cl. CPC H10B 10/12; H01L 21/823807; H01L 21/823871; H01L 21/823885; H01L 27/092; H01L 29/66666; H01L 29/7827

(57) ABSTRACT

A semiconductor device, includes a source and drain bottom epitaxial layer positioned on top of a dielectric substrate. A metal gate is positioned on top of the bottom epitaxial layer. A source and drain top epitaxial layer is positioned on top of the metal gate. A first and second semiconductor channel pass vertically from the source and drain top epitaxial layer through the metal gate to the source and drain bottom epitaxial layer. First and second metal contacts are conductively coupled to the first and second semiconductor channels. First and second metal vias are formed on a backside of the source and drain bottom epitaxial layer and arranged in conductive contact with the first and second semiconductor channels. A metal layer is formed on a backside of the first and second metal vias.

### BACKGROUND

### Technical Field

The present disclosure generally relates to semiconductor device fabrication, and more particularly, to an SRAM formation for vertical FET with backside contact.

### Description of the Related Art

In semiconductor device manufacture, static random-access memory (SRAM) devices are incorporating next generation technologies including, for example, vertical field effect transistors (VFET). The formation of VFET devices poses many challenges in the effort to connect different device elements. For example, some current VFET structures that incorporate a pull-up and pull-down inverter connect the source and drain areas through a doped semiconductor area. Using the doped semiconductor can induce higher resistance and low speed signaling. In another proposed approach, the source and drain are connected through a metal line under the metal gate. To provide connectivity, the metal line wraps around the source and drain areas of the pull-up/pull-down elements, the gate, and a cross-couple contact. The metal line under the source and drain areas uses additional wiring to connect to the top side of the device.

### SUMMARY

According to another embodiment of the present disclosure, a semiconductor chip device is provided. The semiconductor device includes a source and drain bottom epitaxial layer. A metal gate is positioned on top of the bottom epitaxial layer. A source and drain top epitaxial layer is positioned on top of the metal gate. A first semiconductor channel is positioned passing vertically from the source and drain top epitaxial layer through the metal gate to the source and drain bottom epitaxial layer. A second semiconductor channel is positioned passing vertically from the top epitaxial layer through the metal gate to the source and drain bottom epitaxial layer. A first metal contact is conductively coupled to the first semiconductor channel. A second metal contact is conductively coupled to the second semiconductor channel. A first metal via is on a backside of the source and drain bottom epitaxial layer and arranged in conductive contact with the first semiconductor channel. A second metal via is on the backside of the source and drain bottom epitaxial layer and arranged in conductive contact with the second semiconductor channel. A metal layer is on a backside of the first and second metal vias.

According to an embodiment of the present disclosure, a vertical FET device is provided. The device includes a first frontside metal gate. A first pull-up transistor element is arranged vertically in the first frontside metal gate. A first pull-down transistor element is arranged vertically in the first frontside metal gate. A first metal layer is positioned under a backside of the first frontside metal gate and electrically couples the first pull-up transistor element to the first pull-down transistor element. A second frontside metal gate is included in the device. A second pull-up transistor element is arranged vertically in the second frontside metal gate. A second pull-down transistor element is arranged vertically in the second frontside metal gate. A second metal layer electrically couples the second pull-up transistor element to the second pull-down transistor element. A first cross-couple conductive metal is in contact with the first frontside metal gate and the second metal layer.

According to an embodiment of the present disclosure, a method of fabricating a semiconductor device is provided. The method includes providing an initial semiconductor structure. An initial semiconductor structure including a dielectric substrate is provided. A source and drain bottom epitaxial layer positioned on top of the dielectric substrate is provided. A metal gate positioned on top of the bottom epitaxial layer and the dielectric substrate is provided. A source and drain top epitaxial layer positioned on top of the metal gate is provided. A first semiconductor channel passing vertically from the source and drain top epitaxial layer through the metal gate to the source and drain bottom epitaxial layer is provided. A second semiconductor channel passing vertically from the top epitaxial layer through the metal gate to the source and drain bottom epitaxial layer is provided. A first metal contact is conductively coupled to the first semiconductor channel. A second metal contact is conductively coupled to the second semiconductor channel. A first metal via is formed on a backside of the source and drain bottom epitaxial layer and arranged in conductive contact with the first semiconductor channel. A second metal via is formed on the backside of the source and drain bottom epitaxial layer and arranged in conductive contact with the second semiconductor channel. A metal layer is formed on a backside of the first and second metal vias.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a cross-sectional view of a starting formation for a semiconductor device, consistent with embodiments of the present disclosure.

FIG. 2 is a cross-sectional view of the semiconductor device of FIG. 1 after bonding of a carrier wafer, consistent with embodiments of the present disclosure.

FIG. 3 is a cross-sectional view of the semiconductor device of FIG. 2 after a wafer flip and removal of a substrate, consistent with embodiments of the present disclosure.

FIG. 4 is a cross-sectional view of the semiconductor device of FIG. 3 after adding metal contacts and adding back end of line layers, consistent with embodiments of the present disclosure.

FIG. 5A is a cross-sectional view of the semiconductor device of FIG. 4, illustrating an equivalent circuit path of an inverter, consistent with embodiments of the present disclosure.

FIG. 5B is a schematic view of the cross-section view of the device of FIG. 5A.

FIG. 6 is a top view of a pull-up and pull-down inverter, consistent with embodiments of the present disclosure.

FIG. 7A is a schematic view of an inverter pair consistent with embodiments shown in FIGS. 7B-11.

FIG. 7B is a top view of the pull-up and pull-down inverter of FIG. 6 after the addition of backside connections, consistent with embodiments of the present disclosure.

FIG. 8 is a top view of the pull-up and pull-down inverter of FIG. 7 after formation of V_{DD} and V_{SS} contacts, consistent with embodiments of the present disclosure.

FIG. 9 is a top view of the pull-up and pull-down inverter of FIG. 8 after formation of bit lines, consistent with embodiments of the present disclosure.

FIG. 10 is a top view of the pull-up and pull-down inverter of FIG. 9 after formation of word line contacts, consistent with embodiments of the present disclosure.

FIG. 11 is a top view of the pull-up and pull-down inverter of FIG. 9 after formation of a word line metal layer, consistent with embodiments of the present disclosure.

FIG. 12 is a cross-sectional view of a pull-up and pull-down inverter along a path shown by the schematic view in FIG. 13, consistent with embodiments of the present disclosure.

FIG. 13 is a top view of a pull-up and pull-down inverter along the cross-section shown in FIG. 12, consistent with embodiments of the present disclosure.

FIG. 14 is a cross-sectional view of a pull-up and pull-down inverter along a path shown by the view in FIG. 15, consistent with embodiments of the present disclosure.

FIG. 15 is a top view of a pull-up and pull-down inverter along the cross-section shown in FIG. 14, consistent with embodiments of the present disclosure.

FIG. 16 is a flowchart of a method of manufacturer for a vertical field effect transistor device, according to an embodiment.

### DETAILED DESCRIPTION

### Overview

Vertical field effect transistor (VFET) fabrication generally involves complex pattern formations in the vertical planes. Conventional VFET fabrication techniques commonly connect elements together using wiring from a wafer's frontside. Since many of the VFET elements are arranged vertically on the wafer, connecting the VFET elements to shared conductive features can be challenging from a lithography perspective. In applications that use pass-gate and cross-coupled inverter pairs for example, wrap-around metallization may be used to ensure connectivity between the many various elements. However, wrap-around formations require substantial patterning around other features. Thus, more complexity is added to the fabrication processes used to manufacture a VFET. In addition, the spacing between the wrap around metal and the metal gate can be narrow enough that a high-K parasitic capacitance may be introduced.

In general, the subject disclosure describes a process for providing a semiconductor device that includes forming a VFET structure. The VFET of the subject disclosure may include a pull-up/pull-down inverter. The VFET may be used in for example, a static random-access memory (SRAM) device. The semiconductor device provides an improvement over conventional VFET devices by including a metal layer and conductive contacts formed on the backside of the VFET. The metal layer provides a shared connection for the pull-up and pull-down elements in the inverter. In addition, the metal layer connects one inverter in the SRAM device to an adjoining inverter via a cross-couple element without needing to resort to complicated feature patterning such as wrap-around metallization. It should also be appreciated that the backside contacts space the backside metal layer from the metal in the gate region of the inverter. The spacing formed between metal layers of the subject device is wider than the spacing present in some wrap-around metal connects for known VFET designs, thus lowering the parasitic capacitance in the backside of the device.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Example Methodology of Manufacture

In the following, a process describes a general method of forming a semiconductor device that uses a backside conductive connection for an inverter pair. In some embodiments, the backside connection provides a conductive element for cross-coupling to an adjoined inverter pair of for example, a SRAM device. The fabrication of the devices described herein below can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, devices discussed herein can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

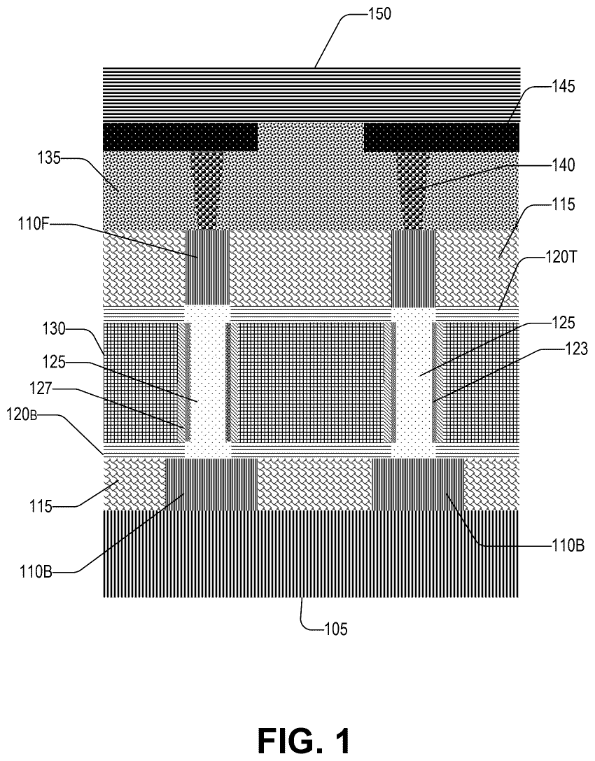

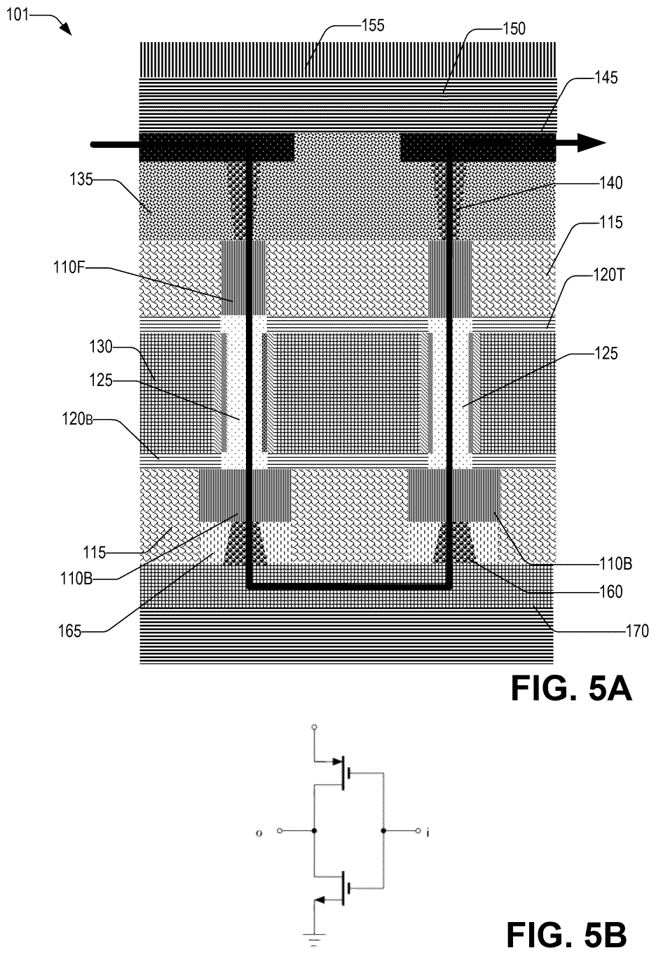

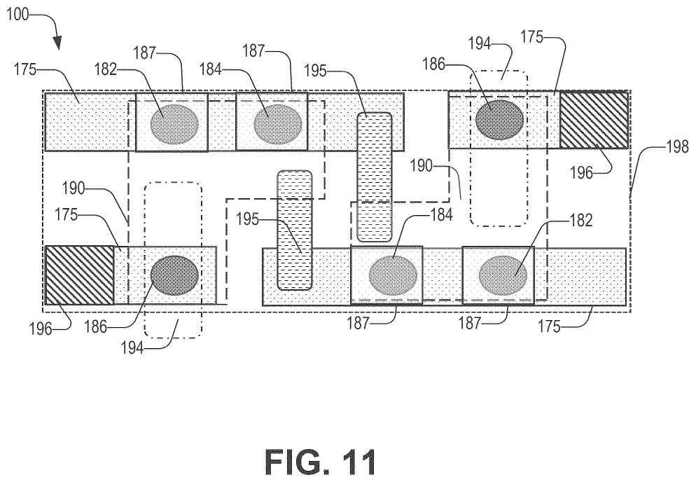

FIG. 1 is a cross-sectional view of a starting formation for a semiconductor device. A final form of an inverter 101 that is formed from the formation in FIG. 1 can be previewed in FIG. 5. FIG. 11 shows a top view perspective of a cross-coupled inverter pair 100 that may be formed starting from the formation in FIG. 1.

In FIG. 1, some embodiments may include a base dielectric substrate 105 providing support for layers above the substrate 105. In one embodiment, the base dielectric substrate 105 may be a bulk semiconductor substrate formed of, for example, silicon, or other types of semiconductor substrate materials that are commonly used in bulk semiconductor fabrication such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

Vertically formed FET channels 125 may be formed over the substrate 105. One FET channel 125 may be configured as a PFET (or P-channel) and the other channel 125 may be configured as an NFET (or N-channel). The channels 125 may share a metal gate 130. The backside of the channels 125 may be coupled to a backside epitaxial layer 110B. The frontside of the channels 125 may be coupled to a frontside epitaxial layer 110F. The metal gate 130 region may be isolated from frontside elements by a frontside spacer 120T and isolated from backside elements by a backside spacer 120B. Some embodiments may include a gate dielectric 123 and a work function metal 127 isolating the channels 125 from the metal gate 130. Some embodiments may include an interlevel dielectric 115 to insulate the regions around the backside epitaxial layer 110B. Some embodiments may include interlevel dielectric 115 to insulate the regions surrounding the frontside epitaxial layer 110F. Metal vias 140 may be connected to each frontside epitaxial layer 110F. Frontside metal contacts 145 may be electrically connected to each via. An insulator 135 may be present and configured to insulate the vias 140 and metal contacts 145 of each channel from each other. Some embodiments may include a back end of line (BEOL) layer 150 positioned on the frontside of the device and over the metal contacts 145.

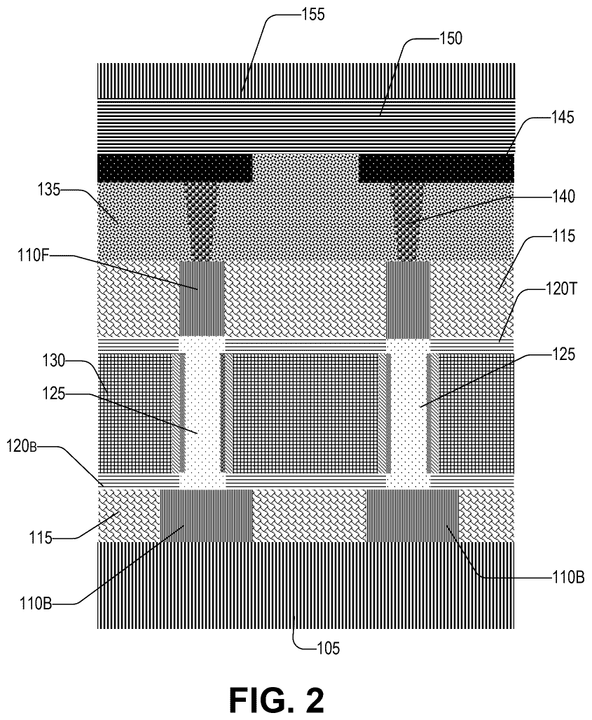

FIG. 2 shows where, in some embodiments, a carrier wafer 155 may be bonded to the frontside of the formation of FIG. 1. The carrier wafer 155 may be positioned in top of the BEOL layer 150.

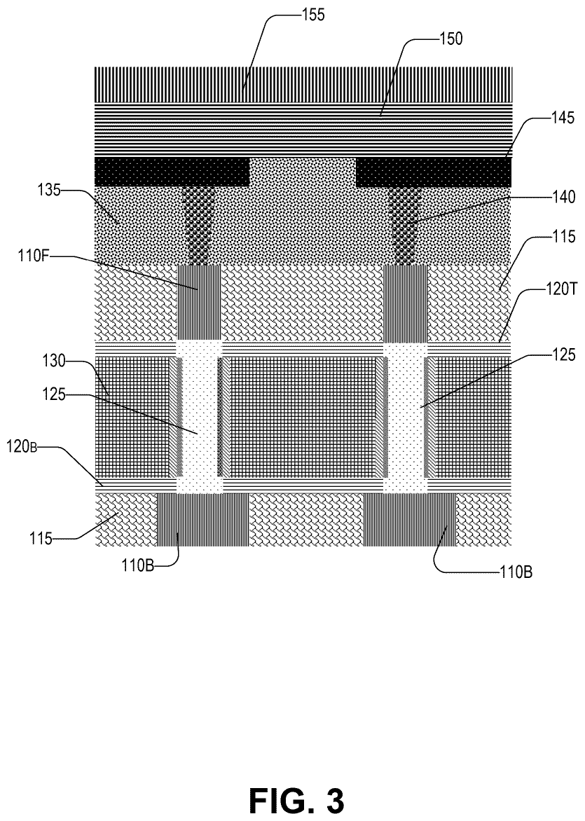

FIG. 3 represents the formation in FIG. 2 after a wafer flip and the removal of the substrate 105. For sake of illustration, the formation is maintained in the same orientation as shown in FIG. 2 but it will be understood that, in practice, the device orientation may be rotated 180 degrees for the remainder of the process.

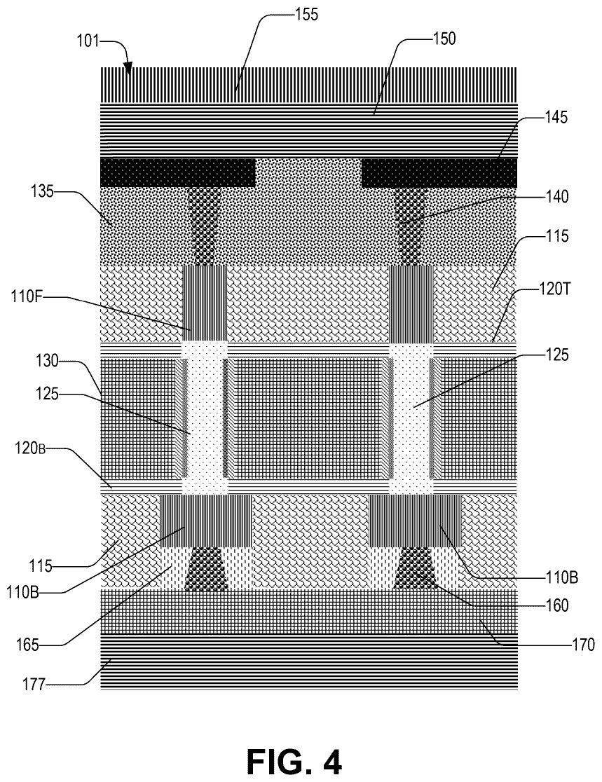

FIG. 4 shows the formation of FIG. 3 after backside metal patterning has been performed. Backside metal vias 160 may be formed on the backside of channels 125. For example, the backside metal vias 160 may be coupled to backside of the backside epitaxial layer 110B. A metal layer 170 may be deposited across the backside of the interlevel dielectric 115 and the backside metal vias 160. An insulator 165 may surround the backside metal vias 160. In some embodiments, a second BEOL layer 177 may be formed on the backside of the metal layer 170. The formation shown in FIG. 4 represents an inverter 101 of the subject disclosure. As shown in FIG. 5A, in one example application, the channel 125 on the right may be an N-channel and the channel 125 on the left may be a P-channel. The metal contact 145 on the left will serve as the V_{DD} source. The signal through the inverter 101 is represented by the path of the arrow. The channel 125 on the right will operate as the pull-down element for the signal output. The metal contact 145 on the right will serve as the V_{SS} for the inverter 101.

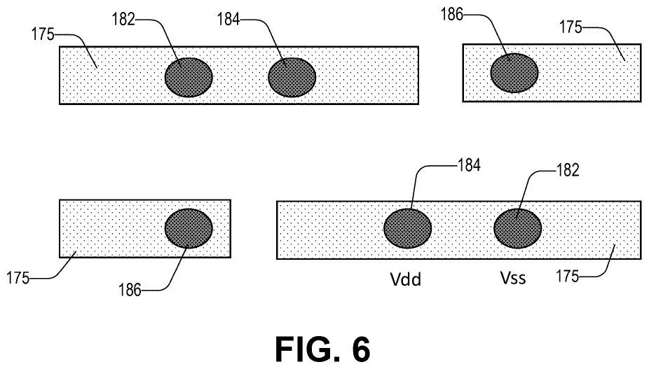

FIGS. 6-11 show a top perspective view of forming connections for a cross-coupled inverter pair 100 of a vertical FET. In FIGS. 6-11, since many of the connections overlap other elements, some elements are shown in shading so that the relative position of underlying elements can remain in view. In addition, some supporting elements (for example, substrates, insulators, etc.) are omitted from view for a clearer illustration and to avoid clutter.

FIG. 6 shows patterns of frontside gates 175 for a vertical FET that are staggered for cross-coupling. The arrangement of features in FIG. 6 may be considered an initial point for forming an inverter pair connection with respect to the present disclosure. A pull-down transistor element 182 and a pull-up transistor element 184 may be formed vertically in the top left instance of a frontside gate 175. To the right of the top left instance of the frontside gate 175 is a second instance of a frontside gate 175 with an integrated pass gate element 186, sometimes simply referred to herein as a pass gate. An inverted version of top instance (a third instance) of the frontside gate 175 with the pull-down transistor element 182 and pull-up transistor element 184 is positioned on the lower right. Another pass gate 186 in a fourth frontside gate 175 is shown to the left of the bottom pull-down transistor element 182 and pull-up transistor element 184 pair.

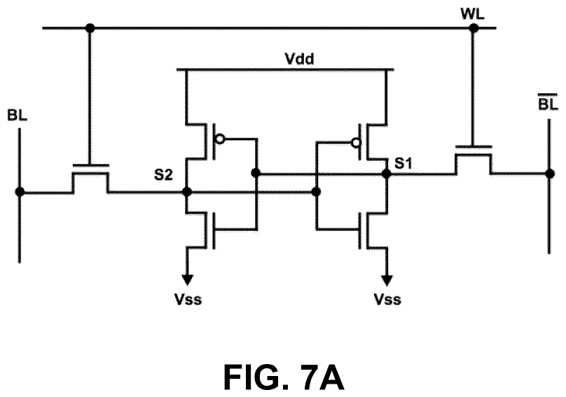

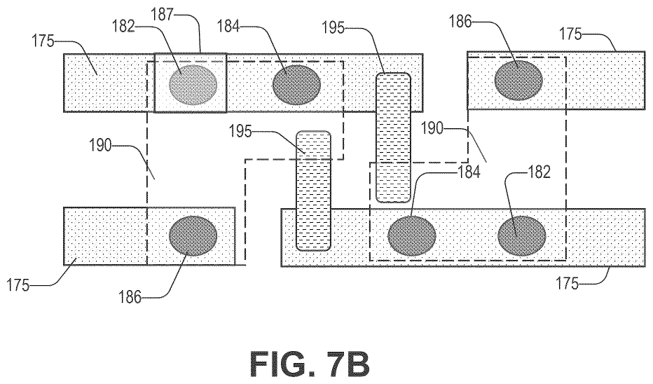

FIG. 7 shows the arrangement in FIG. 6 after a frontside metal contact 187 has been formed on the frontside of the pull-down transistor element 182 for the upper pair. A backside metal source and drain connection 190 (shown in shading) may be formed connecting the pull-down transistor elements 182 to the pull-up transistor elements 184 on respective frontside gates 175. In addition, the backside metal source and drain connection 190 for the upper left pair may be formed connecting the pull-up transistor element 184 to the pass gate 186 on the bottom left. A conductive cross-couple connection 195 maybe formed connecting the frontside gate 175 of each pull-up/pull-down pair 182/184 to the backside metal source and drain connection 190 connecting the opposing pull-up/pull-down pair 182/184.

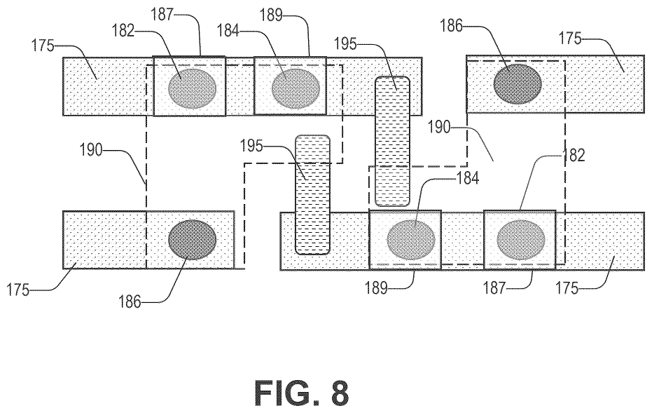

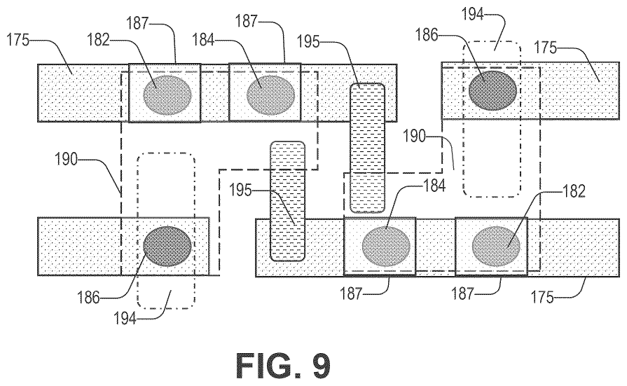

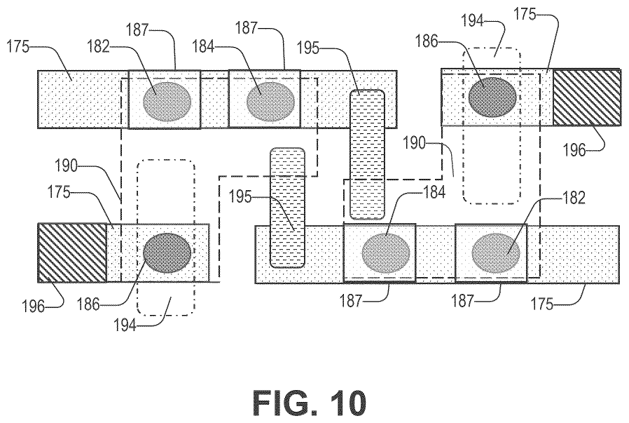

FIG. 8 shows the formation in FIG. 7 after additional frontside metal contacts 187 and 189 have been formed. Frontside metal contacts 187 may represent the VSS points and the metal contacts 189 may represent the VDD points in the inverter pair. FIG. 9 shows a formation in some embodiments that includes adding bit line connections 194 connected to the pass gates 186. The bit line connections 194 are represented by dash-dot outline and are shown as an overlay to represent that the bit line connections 194 may be on a different plane than the pass gates 186. FIG. 10 shows a formation after adding word line contacts 196 to unoccupied areas of the frontside field gates 175 that include the pass gates 186. In FIG. 11, a word line layer 198 (represented by the area in dotted line around the perimeter of the field gates 175) is connected to the inverter pair 100 by connection to the word line contacts 196. The word line layer 198 may be positioned on another plane over (or under) the inverter pair 100.

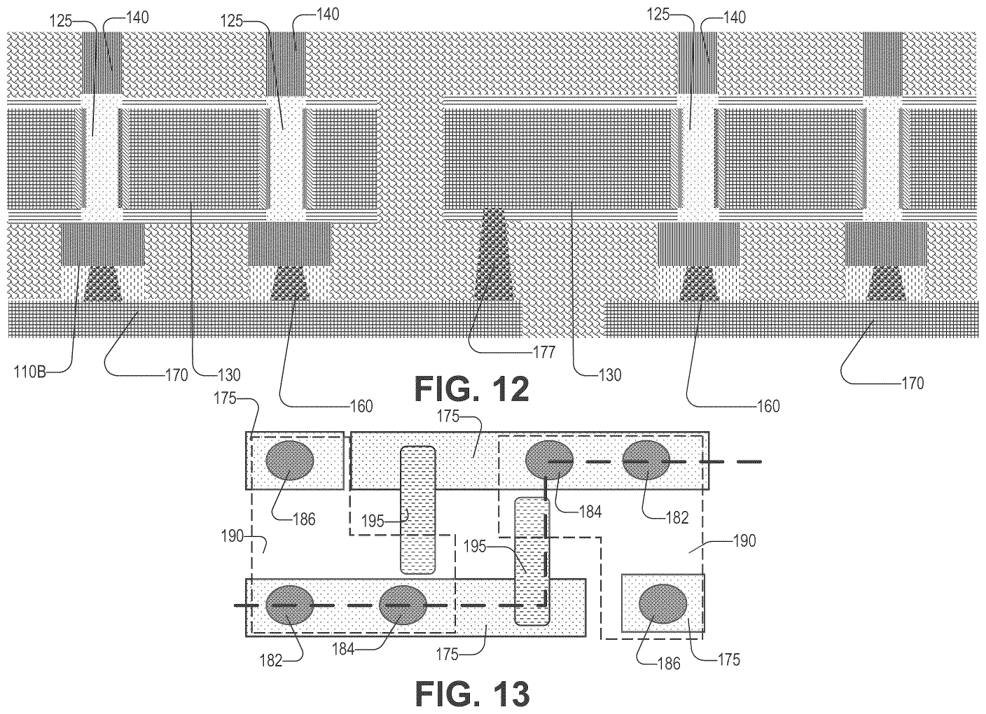

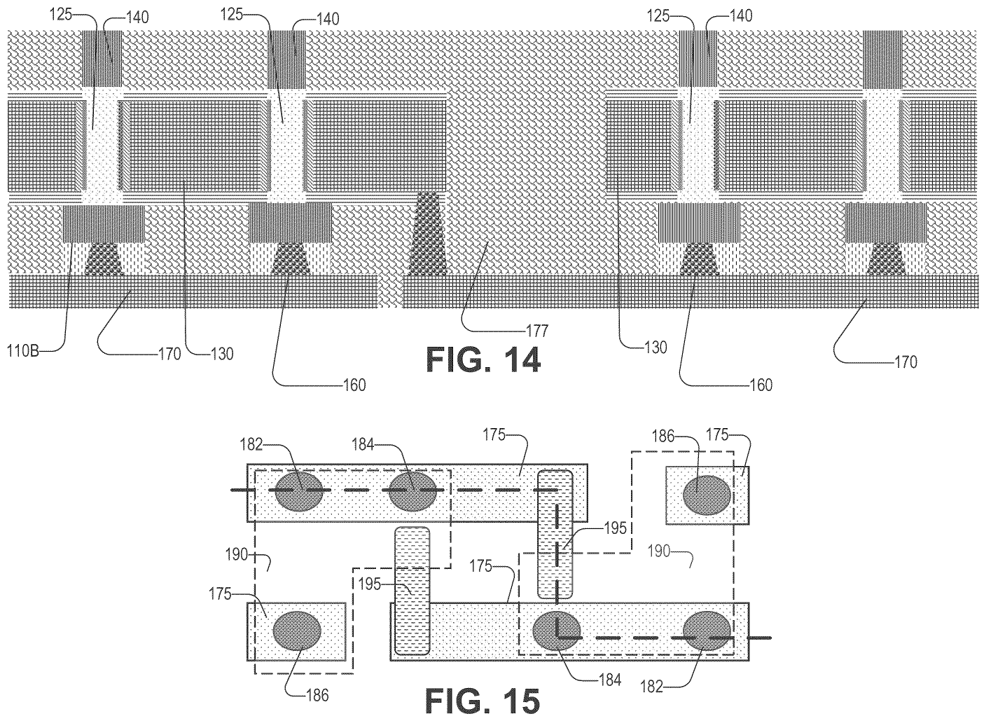

FIG. 12 shows a cross-sectional view of the inverter pair 100 of FIG. 9 (in other words without the bit line and word line connections). In some instances, different enumeration is used between analogous elements since different textures were used to represent like elements. For example, in FIG. 12, the backside metal vias 160 are analogous to the backside metal source and drain connection 190 shown in FIGS. 6-11. The cross-couple connection 177 is analogous to the cross-couple connection 195. The channels 125 in FIG. 12 were referenced as individual pull-down transistor elements 182 and pull-up transistor elements 184 in FIG. 9. The metal gate 130 in FIG. 12 was shown as the frontside gates 175 in FIG. 9. FIG. 13 shows the top view perspective of the elements in FIG. 12 using the enumeration consistent with FIGS. 6-11. In FIG. 13, the perspective shows the path represented by the cross-section of FIG. 12. Similarly, FIG. 15 shows the path of elements represented by the cross-section shown in FIG. 14.

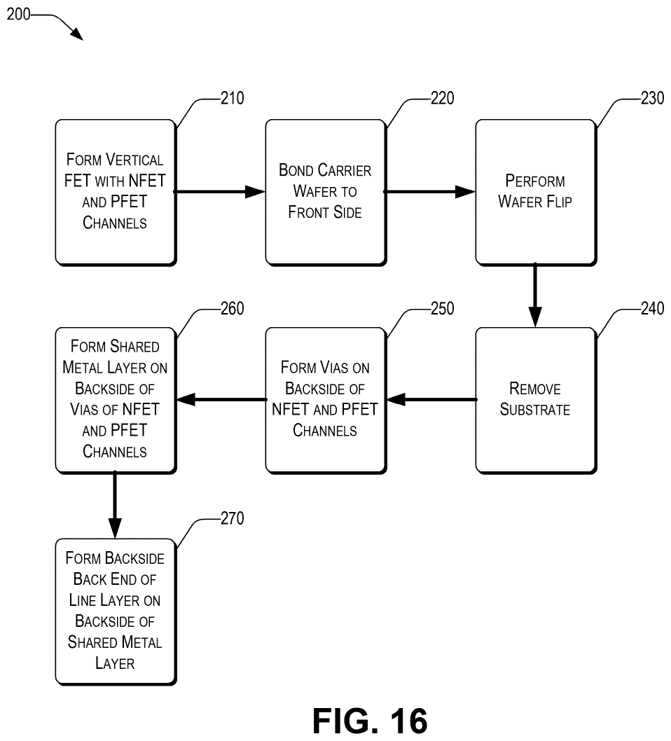

FIG. 16 shows a method 200 for manufacturing a VFET device according to an embodiment. A VFET with NFET and PFET channels is formed 210. In some embodiments, a wafer carrier may be bonded 220 to the frontside of the VFET. In some embodiments, a wafer flip may be performed 230. A substrate may be removed 240 from the backside of the VFET. Metal contact vias may be formed 250 in contact with the NFET and PFET channels. A shared metal layer may be formed 260 in contact with the metal contact vias of both the NFET and PFET channels. In some embodiments, a backside back end of line layer may be formed over the shared metal layer.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a source and drain bottom epitaxial layer;
a metal gate positioned on top of the bottom epitaxial layer;
a source and drain top epitaxial layer positioned on top of the metal gate;
a first semiconductor channel passing vertically from the source and drain top epitaxial layer through the metal gate to the source and drain bottom epitaxial layer;
a second semiconductor channel passing vertically from the source and drain top epitaxial layer through the metal gate to the source and drain bottom epitaxial layer;
a first metal contact conductively coupled to the first semiconductor channel;
a second metal contact conductively coupled to the second semiconductor channel;
a first metal via on a backside of the source and drain bottom epitaxial layer and arranged in conductive contact with the first semiconductor channel;
a second metal via on the backside of the source and drain bottom epitaxial layer and arranged in conductive contact with the second semiconductor channel; and
a metal layer on a backside of the first and second metal vias.

2. The semiconductor device of claim 1, wherein the first semiconductor channel is configured to be a vertical PFET and the second semiconductor channel is configured to be a vertical NFET.

3. The semiconductor device of claim 1, further comprising a pass gate coupled to the metal layer.

4. The semiconductor device of claim 1, wherein the metal layer is on a backside of the metal gate and wherein the first metal contact and the second metal contact are on a frontside of the metal gate.

5. The semiconductor device of claim 1, further comprising a first back end of line layer on a backside of the metal layer.

6. The semiconductor device of claim 5, further comprising a second back end of line layer on a frontside of the metal gate.

7. The semiconductor device of claim 6, further comprising a carrier wafer on a frontside of the second back end of line layer.

8. A vertical FET device, comprising:
a first frontside metal gate;
a first pull-up transistor element arranged vertically in the first frontside metal gate;
a first pull-down transistor element arranged vertically in the first frontside metal gate;
a first metal layer positioned under a backside of the first frontside metal gate and electrically coupling the first pull-up transistor element to the first pull-down transistor element;
a second frontside metal gate;
a second pull-up transistor element arranged vertically in the second frontside metal gate;
a second pull-down transistor element arranged vertically in the second frontside metal gate;
a second metal layer electrically coupling the second pull-up transistor element to the second pull-down transistor element; and
a first cross-couple conductive metal in contact with the first frontside metal gate and the second metal layer.

9. The vertical FET device of claim 8, further comprising a second cross-couple conductive metal in contact with the second frontside metal gate and the first metal layer.

10. The vertical FET device of claim 8, further comprising a pass gate coupled to either the first metal layer or the second metal layer.

11. The vertical FET device of claim 10, further comprising a bit line coupled to the pass gate.

12. The vertical FET device of claim 11, further comprising a word line coupled to the bit line.

13. The vertical FET device of claim 8, further comprising a first metal via connected to a frontside of the first metal layer and coupled to the first pull-up transistor element through the backside of the first frontside metal gate.

14. A method of fabricating a semiconductor device, comprising:
providing an initial semiconductor, comprising:
providing a dielectric substrate;
providing a source and drain bottom epitaxial layer positioned on top of the dielectric substrate;
positioning a metal gate on top of the bottom epitaxial layer and the dielectric substrate;
positioning a source and drain top epitaxial layer on top of the metal gate;
providing a first semiconductor channel passing vertically from the source and drain top epitaxial layer through the metal gate to the source and drain bottom epitaxial layer;
providing a second semiconductor channel passing vertically from the top epitaxial layer through the metal gate to the source and drain bottom epitaxial layer;
conductively coupling a first metal contact to the first semiconductor channel; and
conductively coupling a second metal contact to the second semiconductor channel;
forming a first metal via on a backside of the source and drain bottom epitaxial layer and arranged in conductive contact with the first semiconductor channel;
forming a second metal via on the backside of the source and drain bottom epitaxial layer and arranged in conductive contact with the second semiconductor channel; and
forming a metal layer on a backside of the first and second metal vias.

15. The method of claim 14, further comprising forming the first semiconductor channel as a PFET.

16. The method of claim 14, further comprising forming the second semiconductor channel as an NFET.

17. The method of claim 14, wherein the metal layer is on a backside of the metal gate and wherein the first metal contact and the second metal contact are on a frontside of the metal gate.

18. The method of claim 14, further comprising forming a first back end of line layer on a backside of the metal layer.

19. The method of claim 18, further comprising forming a second back end of line layer on a frontside of the metal gate.

20. The method of claim 19, further comprising forming a carrier wafer on a frontside of the second back end of line layer.
